(19) United States
(12) Patent Application Publication
(10) Pub. No.: US 2026/0177590 A1
(43) Pub. Date: Jun. 25, 2026

(54) ANTI-TAMPERING AND OVER-CURRENT DETECTION METHODS

(71) Applicant: Allegro MicroSystems, LLC, Manchester, NH (US)

(72) Inventors: Yannick Vuillermet, La Motte Servolex (FR); Alexander Latham, Harvard, MA (US); Rémy Lassalle-Balier, Bures sur Yvette (FR); Conrado Rossi, Montevideo (UY)

(73) Assignee: Allegro MicroSystems, LLC, Manchester, NH (US)

(21) Appl. No.: 18/989,072

(22) Filed: Dec. 20, 2024

(51) Int. Cl. G01R 15/20; G01R 19/165

(52) U.S. Cl. CPC G01R 15/205; G01R 19/16504

(57) ABSTRACT

A sensor, including: a gradiometer including a plurality of magnetoresistors, the gradiometer being configured to generate a sensing signal in response to a magnetic field that is at least in part produced as a result of an electrical current flowing through a conductor; and electronic circuitry configured to detect an electrical current consumption of the gradiometer, compare the electrical current consumption against at least one of a first threshold and a second threshold, and output an indication that the sensor is subject to tampering based on an outcome of the comparison.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with the flow of electrical current through a conductor. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: a sensing module including a plurality of magnetic field sensing elements, the sensing module being arranged to generate a sensing signal, at least in part, in response to a feedback magnetic field; a magnetic feedback loop that is configured to generate the feedback magnetic field, the magnetic feedback loop including a feedback coil and a coil driver, the coil driver being arranged to drive the feedback coil with drive current that is generated based on the sensing signal, the drive current having a minimum value and a maximum value; and electronic circuitry configured to identify a first threshold that corresponds to the maximum value, identify a second threshold that is based on one of (i) maximum resistance associated with a first portion of the sensing module and a maximum resistance associated with a second portion of the sensing module, and (ii) minimum resistance associated with the first portion and a minimum resistance associated with the second portion, detect whether the first threshold is exceeded by the drive current, detect whether the second threshold is exceeded by the sensing signal, and output an indication that the sensor is subject to tampering when the first threshold is exceeded by the drive current and the second threshold is not exceeded by the sensing signal.

According to aspects of the disclosure, a sensor is provided, comprising: a first sensing element that is configured to generate a first sensing signal, the first sensing signal being generated in response to a magnetic field, the first sensing signal having a first maximum value and a first minimum value; a second sensing element that is configured to generate a second sensing signal, the second sensing signal being generated in response to the magnetic field, the second sensing signal having a second maximum value and a second minimum value; and an electronic circuitry that is configured to: identify a first threshold that is based on the first maximum value, a second threshold that is based on the first minimum value, a third threshold that is based on second maximum value, and a fourth threshold that is based on the second minimum value; compare the first sensing signal against the first threshold; compare the first sensing signal against the second threshold; compare the second sensing signal against third threshold; compare the second sensing signal against the fourth threshold; detect whether at least one of a first condition and a second condition are satisfied based on an outcome of the comparisons; and output an indication that the sensor is subject to tampering when either the first condition or the second condition is satisfied; wherein the first condition is satisfied when the first sensing signal is greater than the first threshold, the first sensing signal is greater than the second threshold, the second sensing signal is greater than the third threshold, and the second sensing signal is greater than the fourth threshold, and wherein the second condition is satisfied when the first sensing signal is less than the first threshold, the first sensing signal is less than the second threshold, the second sensing signal is less than the third threshold, and the second sensing signal is less than the fourth threshold.

According to aspects of the disclosure, a system is provided, comprising: a first sensing bridge including a first, second, third, and fourth sensing elements, the first and second sensing elements being arranged to form a first leg of the first sensing bridge, the third and fourth sensing elements being arranged to form a second leg of the first sensing bridge, the first and second legs of the first sensing bridge being coupled in parallel to each other; an electronic circuitry configured to: identify a first threshold, a second threshold, a third threshold, and a fourth threshold, the first threshold being smaller than a maximum resistance of at least one of the first and third sensing elements, the second threshold being larger than a minimum resistance of at least one of the first and third sensing elements, the third threshold being smaller than a maximum resistance of at least one of the second and fourth sensing elements, and the fourth threshold being larger than a minimum resistance of at least one of the second and fourth sensing elements; identify a first resistance of at least one of the first and third sensing elements, the first resistance being an instant resistance; identify a second resistance of at least one of the second and fourth sensing elements, the second resistance being an instant resistance; compare the first resistance against the first threshold; compare the first resistance against the second threshold; compare the second resistance against third threshold; compare the second resistance against the fourth threshold; and detect whether at least one of a first condition and a second condition is satisfied based on an outcome of the comparisons; and output an indication that the sensor is subject to tampering when either the first condition or the second condition is satisfied; wherein the first condition is satisfied when the first resistance is greater than the first threshold, the first resistance is greater than the second threshold, the second resistance is greater than the third threshold, and the second resistance is greater than the fourth threshold, and wherein the second condition is satisfied when the first resistance is less than the first threshold, the first resistance is less than the second threshold, the second resistance is less than the third threshold, and the second resistance is less than the fourth threshold.

According to aspects of the disclosure, a sensor is provided, comprising: a first sensing bridge that is configured to generate a first sensing signal, the first sensing signal being generated in response to a magnetic field, the first sensing bridge having a first minimum resistance and a first maximum resistance; a second sensing bridge that is configured to generate a second sensing signal, the second sensing signal being generated in response to the magnetic field, the second sensing bridge having a second minimum resistance and a second maximum resistance, the second sensing bridge being rotated at approximately 90 degrees relative to the first sensing bridge; and an electronic circuitry that is configured to: identify a first threshold that is based on the first maximum resistance, a second threshold that is based on the first minimum resistance, a third threshold that is based on the second maximum resistance, and a fourth threshold that is based on the second minimum resistance; identify a first resistance of the first sensing bridge, the first resistance being an instant resistance of the first sensing bridge; identify a second resistance of the second sensing bridge, the second resistance being an instant resistance of the second sensing bridge; compare the first resistance against the first threshold; compare the first resistance against the second threshold; compare the second resistance against third threshold; compare the second resistance against the fourth threshold; detect whether at least one of a first condition, a second condition, a third condition, and a fourth condition are satisfied based on an outcome of the comparisons; and output an indication that the sensor is subject to tampering when any one of the first condition, second condition, third condition, and fourth condition is satisfied; wherein the first condition is satisfied when: the first resistance is greater than the first threshold, the first resistance is greater than the second threshold, the second resistance is less than the third threshold, and the second resistance is greater than the fourth threshold; wherein the second condition is satisfied when: the first resistance is less than the first threshold, the first resistance is less than the second threshold, the second resistance is less than the third threshold, and the second resistance is greater than the fourth threshold; wherein the third condition is satisfied when: the first resistance is less than the first threshold, the first resistance is greater than the second threshold, the second resistance is greater the third threshold, and the second resistance is greater than the fourth threshold; wherein the fourth condition is satisfied when: the first resistance is less than the first threshold, the first resistance is greater than the second threshold, the second resistance is less than the third threshold, and the second resistance is less than the fourth threshold.

According to aspects of the disclosure, a sensor is provided, comprising: a sensing module including a plurality of magnetic field sensing elements, the sensing module being arranged to generate a sensing signal, at least in part, in response to a reference magnetic field and a primary magnetic field that is generated as a result of an electrical current flowing through a conductor, the reference magnetic field having a first frequency and the primary magnetic field having a second frequency that is different from the first frequency; a coil that is configured to generate the reference magnetic field; and electronic circuitry configured to: filter the sensing signal so as to block components of the sensing signal that correspond to the second frequency; calculate, based on the filtered sensing signal, a value of a metric that is at least in part indicative of a sensitivity of the sensing module; compare the value of the metric against a threshold; and output an indication that the sensor is subject to tampering when the value of the metric is less than the threshold.

According to aspects of the disclosure, a sensor is provided, comprising: a gradiometer including a plurality of magnetoresistors, the gradiometer being configured to generate a sensing signal in response to a magnetic field that is at least in part produced as a result of an electrical current flowing through a conductor; and electronic circuitry configured to detect an electrical current consumption of the gradiometer, compare the electrical current consumption against at least one of a first threshold and a second threshold, and output an indication that the sensor is subject to tampering based on an outcome of the comparison.

### BRIEF DESCRIPTION OF THE DRAWINGS

The foregoing features may be more fully understood from the following description of the drawings in which:

FIG. 1A is a diagram of an example of a sensing bridge, according to aspects of the disclosure;

FIG. 1B is a diagram of an example of a sensing bridge, according to aspects of the disclosure;

FIG. 1C is a diagram of an example of a sensing bridge, according to aspects of the disclosure;

FIG. 1D is a diagram of an example of a sensing module, according to aspects of the disclosure;

FIG. 2A is a diagram illustrating an example of one possible use of the sensing bridge of FIG. 1A, according to aspects of the disclosure;

FIG. 2B is a diagram illustrating an example of one possible use of the sensing bridge of FIG. 1A, according to aspects of the disclosure;

FIG. 3A is a diagram illustrating an example of one possible use of the sensing bridge of FIG. 1A, according to aspects of the disclosure;

FIG. 3B is a diagram illustrating an example of one possible use of the sensing bridge of FIG. 1A, according to aspects of the disclosure;

FIG. 4A is a diagram illustrating an example of one possible use of the sensing bridge of FIG. 1A, according to aspects of the disclosure;

FIG. 4B is a diagram illustrating an example of a sensor, according to aspects of the disclosure;

FIG. 5A is a graph of a response curve of the resistance of a sensing element, according to aspects of the disclosure;

FIG. 5B is a graph of a response curve of a feedback coil, according to aspects of the disclosure;

FIG. 6A is a flowchart of an example of a process, according to aspects of the disclosure;

FIG. 6B is a graph illustrating aspects of the operation of a sensor, according to aspects of the disclosure;

FIG. 7 is a schematic diagram illustrating a configuration of a magnetic field sensor, according to aspects of the disclosure;

FIG. 8 is a graph of a response curve of a sensing signal, according to aspects of the disclosure;

FIG. 9A is a diagram illustrating an example of one possible use of the sensing bridge of FIG. 1A, according to aspects of the disclosure;

FIG. 9B is a diagram of an example of a pair of sensing bridges, according to aspects of the disclosure.

FIG. 10 is a graph illustrating aspects of the operation of a sensor, according to aspects of the disclosure;

FIG. 11 is a flowchart of an example of a process, according to aspects of the disclosure; and

FIG. 12 is a flowchart of an example of a process, according to aspects of the disclosure.

### DETAILED DESCRIPTION

In current metering applications, using magnetic technology, one classical tampering method is to place a large magnet close to the current sensor. This may cause the magnetic field sensing elements that are part of the sensor to become highly saturated, making the metering impossible. The present disclosure provides an example of several techniques for detecting tampering in a magnetic field sensor.

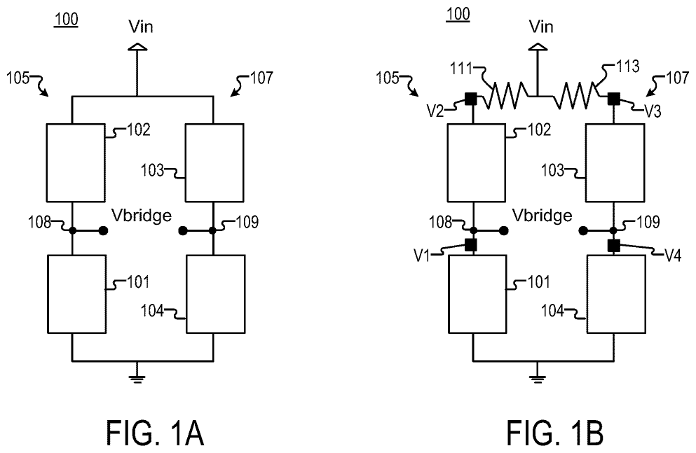

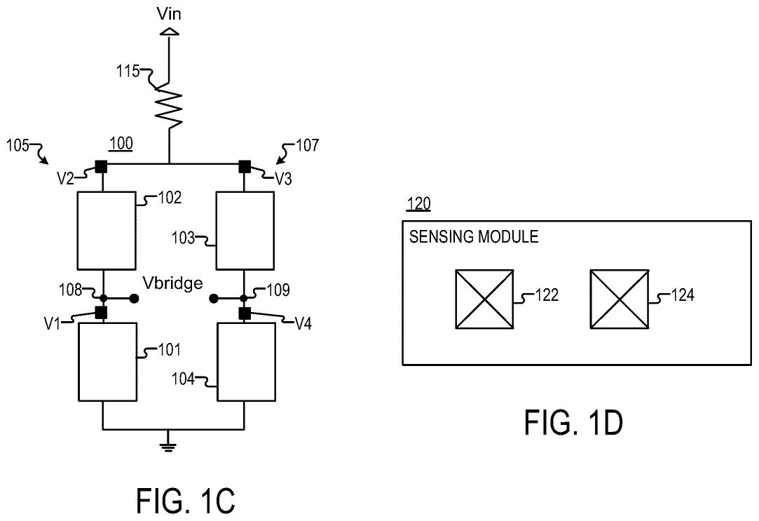

FIG. 1A is a diagram of an example of a sensing bridge 100, according to aspects of the disclosure. As illustrated, sensing bridge 100 may include legs 105 and 107 that are coupled in parallel between a voltage source and ground. Leg 105 may include sensing elements 101 and 102, and leg 107 may include sensing elements 103 and 104. A differential signal Vbridge may be output on nodes 108 and 109. The differential signal Vbridge may be indicative of a magnetic field that is sensed by the sensing bridge 100. According to the present example, sensing elements 101, 102, 103, and 104 are giant magnetoresistance (GMR) elements. However, alternative implementations are possible in which any of sensing elements 101, 102, 103, and 104 is a different type of magnetoresistor, such as an anisotropic magnetoresistance (AMR) element or a tunneling magnetoresistance (TMR) element.

FIG. 1B is a diagram of sensing bridge 100, according to another implementation. In the example of FIG. 1B, sensing bridge 100 is provided with resistors 111 and 113. Resistor 111 may be coupled in series with leg 105 and resistor 113 may be coupled in series with leg 107. Voltage probing points V1, V2, V3, and V4 may be provided in sensing bridge 100, as shown. As is discussed further below, resistor 111, and voltage probing points V1-V2, may be used to estimate the resistance of sensing elements 102 and 101 (or leg 105), and resistor 113, together with voltage probing points V3-V4, may be used to estimate the resistance of sensing elements 103 and 104 (or leg 107).

FIG. 1C is a diagram of sensing bridge 100, according to yet another implementation. In the example of FIG. 1C, sensing bridge 100 is provided with a resistor 115 and voltage probing points V1, V2, V3, and V4. Resistor 115 may be coupled in series with legs 105 and 107. In some implementations, the total equivalent resistance of sensing bridge 100 may be calculated based on the voltage at voltage probing point V4 and the resistance of resistor 115.

In some implementations, voltage probing points V1, V2, V3, and V4 may be used to measure the resistance of any one of the resistors in sensing bridge 100, any one of the legs in sensing bridge 100, or the resistance of the entire sensing bridge 100. The resistance may be determined based on the voltage Vin that is used to drive the sensing bridge 100. For example, the resistance of sensing element 102, in the bridge topology of FIG. 1D, may be determined according to the equation of

$${R}_{2} = \frac{{V}_{2} - {V}_{1}}{{V}_{IN} - {V}_{2}} \times {Ref}_{1} ,$$

where is the resistance of resistor 111, V1 is the voltage at voltage probing point V1, V2 is the voltage at voltage probing point V2, and Vin is the input voltage of bridge 100.

FIG. 1D is a diagram of a sensing module 120, according to aspects of the disclosure. As illustrated, sensing module 120 may include magnetic field sensing elements 122 and 124. According to the example of FIG. 1D, sensing elements 122 and 124 are planar Hall elements. However, alternative implementations are possible in which sensing elements 122 and 124 are vertical Hall elements and/or any other suitable type of magnetic field sensing element.

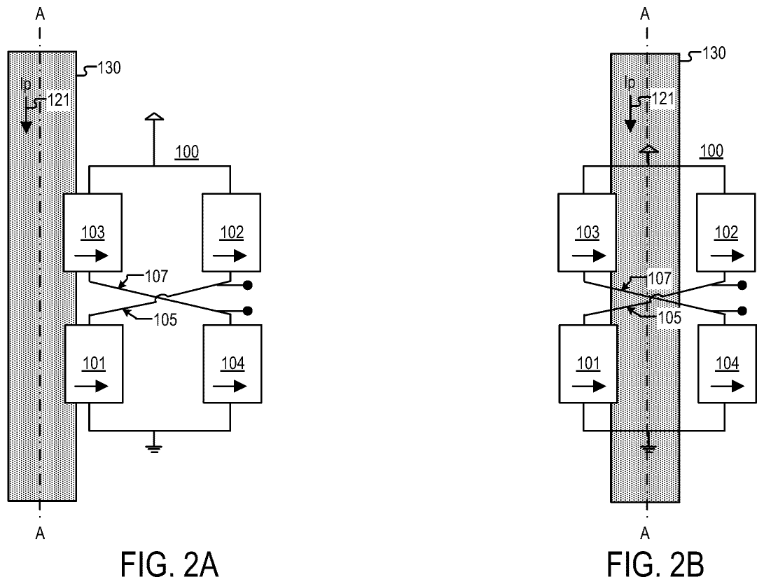

FIG. 2A is a diagram illustrating one possible use of the sensing bridge 100, according to aspects of the disclosure. In the example of FIG. 2A, sensing bridge 100 is used to measure the level of electrical current Ip, which flows through a conductor 130 in the direction indicated by arrow 121. Conductor 130 may have a central longitudinal axis A-A, and sensing bridge 100 may be disposed to the side of central longitudinal axis A-A (and/or to the side of conductor 130). Although, in the example of FIG. 2A, sensing elements 101 and 103 are at least partially disposed above conductor 130, in alternative implementations, sensing elements 101 and 103 (and sensing elements 102 and 104) may be disposed completely to the side of conductor 130. In the example of FIG. 2A, the direction, relative to conductor 130, of the respective axis of maximum sensitivity of each sensing element 101, 102, 103, and 104 is indicated by the arrow inside the rectangle representing the sensing element. However, the present disclosure is not limited to sensing elements 101, 102, 103, and 104 having any specific axis of maximum sensitivity.

FIG. 2B is a diagram illustrating another possible use of sensing bridge 100, according to aspects of the disclosure. In the example of FIG. 2B, sensing bridge 100 is again used to measure the level of electrical current Ip, which flows through conductor 130 in the direction indicated by arrow 121. However, unlike the example of FIG. 2A, sensing bridge 100 is disposed over conductor 130, such that sensing elements 101 and 103 are disposed on one side of axis A-A and sensing elements 102 and 104 are disposed on the opposite side of axis A-A. Sensing elements 101 and 103 may be at least partially disposed over conductor 130 or they may be disposed completely to the side of conductor 130. Sensing elements 102 and 104 may be at least partially disposed over conductor 130 or they may be disposed completely to the side of conductor 130. In the example of FIG. 2B, the direction, relative to conductor 130, of the respective axis of maximum sensitivity of each sensing element 101, 102, 103, and 104 is indicated by the arrow inside the rectangle representing the sensing element. However, the present disclosure is not limited to sensing elements 101, 102, 103, and 104 having any specific axis of maximum sensitivity.

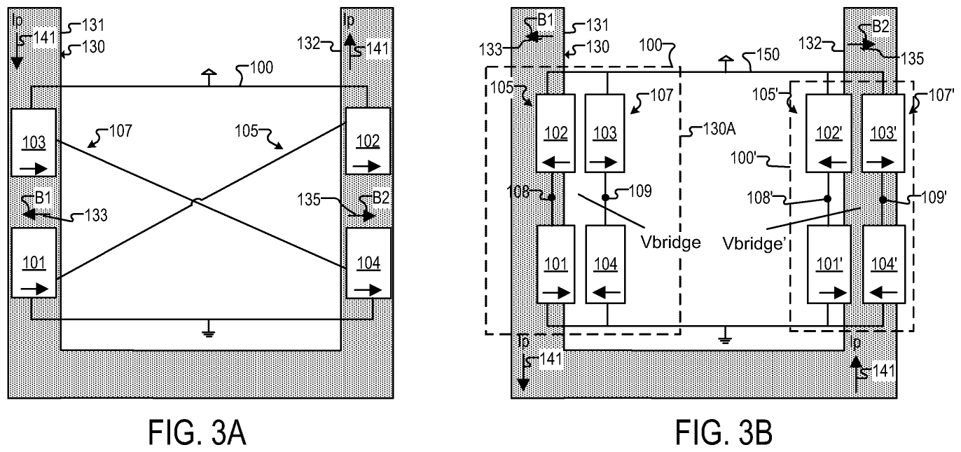

FIG. 3A is a diagram illustrating yet another possible use of sensing bridge 100, according to aspects of the disclosure. In the example, of FIG. 3A, conductor 130 is U-shaped, and sensing bridge 100 is arranged in a gradiometer configuration. Conductor 130 includes side portions 131 and 132. Sensing bridge 100 is again arranged to measure the level of electrical current Ip, which flows through conductor 130. The electrical current Ip may flow through conductor 130 in the direction illustrated by arrows 141. Each of sensing elements 101 and 103 may be at least partially disposed over portion 131. Each of sensing elements 104 and 102 may be at least partially disposed over portion 132.

The axis of maximum sensitivity of sensing element 101 is indicated by the arrow (i.e., right arrow) that is situated inside the box representing sensing element 101. The axis of maximum sensitivity of sensing element 102 is illustrated by the arrow that is situated inside the box representing sensing element 102. The axis of maximum sensitivity of sensing element 103 is indicated by the arrow that is situated inside the box representing sensing element 103. The axis of maximum sensitivity of sensing element 104 is illustrated by the arrow that is situated inside the box representing sensing element 104. The magnetic field B1, which originates from portion 131, and which is the result of the electrical current Ip flowing through portion 131, has a direction that is illustrated by arrow 133. The magnetic field B2, which originates from portion 132, and which is the result of the electrical current Ip flowing through portion 132, has a direction that is illustrated by arrow 135. Stated succinctly, in the example of FIG. 3A, sensing elements 101, 102, 103, and 104 have the same axis of maximum sensitivity, sensing elements 101 and 103 are arranged to sense a magnetic field B1, which has a first direction, and sensing elements 104 and 102 are arranged to sense a magnetic field B2 which has a second direction that is opposite to the first direction.

FIG. 3B is a diagram illustrating yet another possible use of sensing bridge 100, according to aspects of the disclosure. In the example of FIG. 3B, sensing bridge 100 is used to form a differential magnetometer 150 together with a sensing bridge 100′.

The differential magnetometer 150 may be formed by coupling sensing bridge 100 in parallel with sensing bridge 100′ between a voltage source and ground. Sensing bridge 100′ may be identical to sensing bridge 100. As illustrated, sensing bridge 100′ may include legs 105′ and 107′ that are coupled in parallel between the voltage source and ground. Leg 105′ may include sensing elements 101′ and 102′, and leg 107′ may include sensing elements 103′ and 104′. A differential signal Vbridge′ may be output on nodes 108′ and 109′. The differential signal Vbridge′ may be indicative of a magnetic field that is sensed by the sensing bridge 100′. According to the present example, sensing elements 101′, 102′, 103′, and 104′ are giant magnetoresistance (GMR) elements. However, alternative implementations are possible in which any of sensing elements 101′, 102′, 103′, and 104′ is a different type of magnetoresistor, such as an anisotropic magnetoresistance (AMR) element or a tunneling magnetoresistance (TMR) element.

The output of the differential magnetometer 150 may be equal to the difference between signals Vbridge and Vbridge′. It will be recalled that signal Vbridge is the differential output of sensing bridge 100, and signal Vbridge′ is the differential output of sensing bridge 100′. In the example of FIG. 3B, the axis of maximum sensitivity of each of sensing elements 101, 102, 103, 104, 101′, 102′, 103′, and 104′ is indicated by the respective arrow that is situated inside the box representing that sensing element. As illustrated, the respective axis of maximum sensitivity of each of sensing elements 101, 103, 101′ and 103′ may have a first direction, and the respective axis of each of sensing elements 102, 104, 102′, and 104′ may have a second direction that is opposite to the first direction. Sensing bridge 100 may be arranged to sense magnetic field B1 and sensing bridge may be arranged to sense magnetic field B2. The direction of magnetic field B1 at the location of sensing bridge 100 is the same as the direction of the axis of maximum sensitivity of sensing elements 104 and 102 and opposite to the direction of the axes of maximum sensitivity of sensing elements 101 and 103. The direction of magnetic field B2 at the location of sensing bridge 100′ is the same as the direction of the axis of maximum sensitivity of sensing elements 101′ and 103′ and opposite to the direction of the axes of maximum sensitivity of sensing elements 102′ and 104′. In the example of FIG. 3B, the direction of electrical current through conductor 130 is indicated by arrows 141, the direction of the magnetic field B1 is indicated by arrow 133, and the direction of magnetic field B2 is indicated by arrow 135.

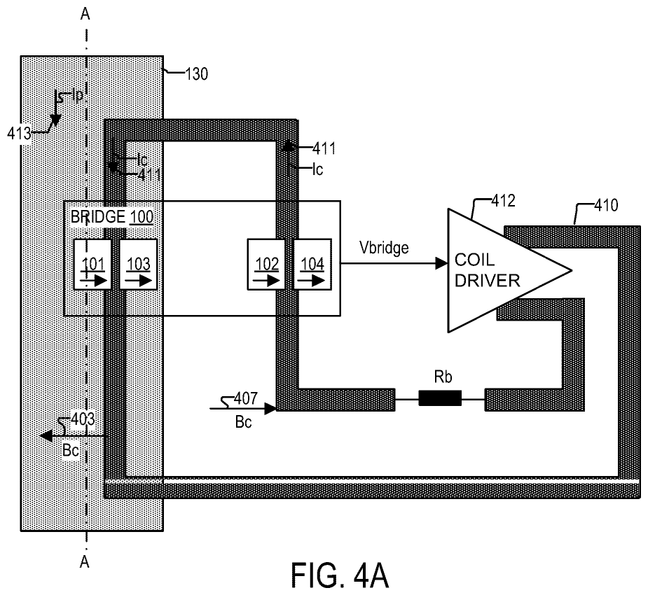

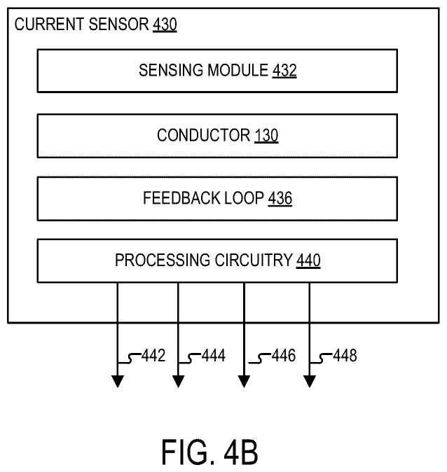

FIG. 4A is a diagram illustrating yet another possible use of sensing bridge 100, according to aspects of the disclosure.

In the example of FIG. 4A, sensing bridge 100 is disposed adjacent to conductor 130 and arranged to measure the level of electrical current Ip through conductor 130. As illustrated, in the example of FIG. 4A, sensing elements 101 and 103 are situated at one location relative to conductor 130 and sensing elements 102 and 104 are situated at a different location relative to conductor 130. The direction of flow of electrical current Ip through the conductor 130 is indicated by arrow 413.

In the example of FIG. 4A, sensing bridge 100 is provided with a feedback loop that includes a feedback coil 410 and a coil driver 412. Specifically, signal Vbridge is provided to a coil driver 412 that is arranged to drive the feedback coil 410. A resistor Rb is provided in the feedback coil 410 and used to measure the level of electrical current Ic through the feedback coil. The direction of the positive flow of electrical current Ic is shown by arrows 411. The feedback coil 410 is arranged to generate a feedback magnetic field Bc, which has the direction indicated by arrow 403 at the location of sensing elements 101 and 103 and the direction indicated by arrow 407 at the location of sensing elements 102 and 104. In the example of FIG. 4A, the direction, relative to conductor 130 and coil 410, of the respective axis of maximum sensitivity of each sensing element 101, 102, 103, and 104 is indicated by the arrow inside the rectangle representing the sensing element. However, the present disclosure is not limited to sensing elements 101, 102, 103, and 104 having any specific axis of maximum sensitivity.

FIG. 4B is a diagram of an example of a current sensor 430, according to aspects of the disclosure. As illustrated, sensor 430 may include a sensing module 432, the conductor 130, a feedback loop 436, and a processing circuitry 440. According to the example of FIG. 4B, conductor 130 is at least partially integrated into the packaging of current sensor 430. However, alternative implementations are possible in which conductor 130 is provided separately from sensor 430.

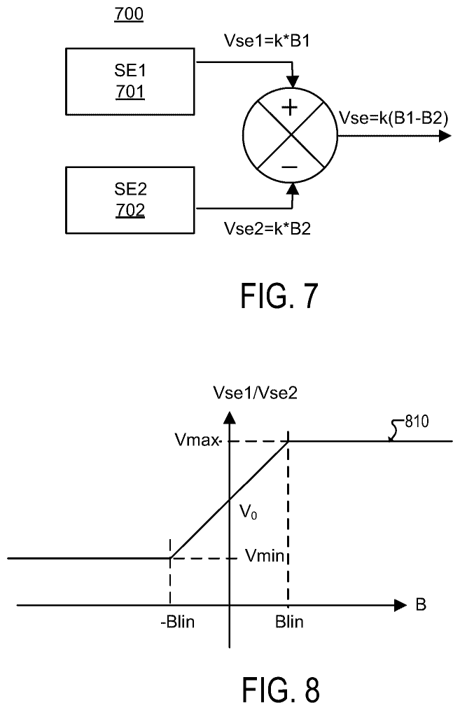

Sensing module 432 may be the same or similar to sensing bridge 100, which is discussed above with respect to FIGS. 1A-3A. Additionally or alternatively, sensing module 432 may be the same or similar to differential magnetometer 150, which is discussed above with respect to FIG. 3B. Additionally or alternatively, sensing module 432 may be the same or similar to sensing module 120. Additionally or alternatively, sensing module 432 may be the same or similar to the sensing circuit 700, which is discussed further below with respect to FIG. 7. In other words, in one respect, FIGS. 1A-4A and 7 provide examples of different ways in which sensing module 432 and/or sensor 430 may be configured.

Feedback loop 436 may include feedback coil 410 and coil driver 412 (shown in FIG. 4A). Coil driver 412 may be configured to drive feedback coil 410 with a drive current that cancels the output of sensing module 432. In one example, the drive current may be proportional to the level of signal Vbridge, which is discussed above with respect to FIG. 1A. Although, in the example of FIG. 4B, sensor 430 is provided with feedback loop 436, alternative implementations are possible in which the feedback loop 436 is omitted. When sensor 430 is provided with a feedback loop, sensor 430 is considered to be in a closed-loop configuration. When sensor 430 is not provided with a feedback loop, sensor 430 is considered to be in an open-loop configuration.

Processing circuitry 440 may include any suitable type of analog or digital circuitry that is normally found in current sensors. By way of example, processing circuitry 440 may include voltage comparators, current comparators, resistors, and/or any other suitable type of circuitry that is configured to measure the voltage or current at different points in the circuitry of sensor 430 and/or compare the measured voltage or current to predetermined threshold, one or more digital-to-analog converters (DACs), one or more analog-to-digital converts (ADCs), one or ore filters (analog or digital), one or more amplifiers, a digital signal processor (e.g., a general-purpose processor or a special-purpose processor), and/or any other suitable type of electronic circuitry that is normally found in current sensors.

In operation, processing circuitry 440 may generate signals 442, 444, 446, and 448. Signal 442 may be generated based on the output of sensing module 432, and it may be indicative of the level of electrical current through conductor 130. Signal 442 may be generated by using any suitable method that is employed by current sensors known in the art. Signal 444 may be a diagnostic signal that is indicative of whether sensor 430 is subject to a tampering condition. For instance, if the value of signal 444 is ‘1’, this may indicate that sensor 430 is subject to tampering. On the other hand, if the value of signal 444 is ‘0’ this may indicate that sensor 430 is not subject to tampering. Output signal 446 may be a diagnostic signal that indicates whether sensor 430 is subject to an overcurrent condition. For instance, if the value of signal 446 is ‘1’, this may indicate that sensor 430 is subject to an overcurrent condition. On the other hand, if the value of signal 446 is ‘O’ this may indicate that sensor 430 is not subject to an overcurrent condition. Signal 448 may be a diagnostic signal that indicates whether feedback loop 436 has failed. For instance, if the value of signal 448 is ‘1’, this may indicate that the feedback loop 436 has failed. On the other hand, if the value of signal 448 is ‘0’ this may indicate that feedback loop 436 is operating normally.

As noted above, sensor 430 is considered to be subject to tampering, when sensor 430 is exposed to a very large magnetic field that causes sensor 430 to operate outside of its linear range and/or become saturated. In some implementations, sensor 430 may be considered subject to a tampering condition when sensor 430 is subjected to a stray field which cannot be rejected by any stray field rejection mechanisms that are provided in sensor 430. Similarly, sensor 430 may be subject to an overcurrent condition when the current Ip (shown in FIGS. 1A-4A) that is being measured by sensor 430 may be so large that the magnetic field generated by the current Ip (and/or conductor 130) causes sensor 430 to operate outside of its linear range and/or become saturated. Under the nomenclature of the present disclosure, the current Ip is also referred to as “primary current”. In one respect, FIGS. 1A-4B, provide examples of different ways in which the sensing module 432 and/or conductor 130 may be configured (independently and in relation to each other). Although, in the example of FIG. 4B, each of signals 444-448 is output on a different line, alternative implementations are possible in which signals 444-448 are output on the same line (e.g., by using error codes, etc.). Signals 442-448 may be provided to external circuitry that is connected to sensor 430. The provision of signal 444-448 may enable the external circuitry to detect whether sensor 430 is experiencing a failure or otherwise deviating from its normal operation, and it makes sensor 430 especially well-suited for various safety-critical applications, such as those found in electric vehicles.

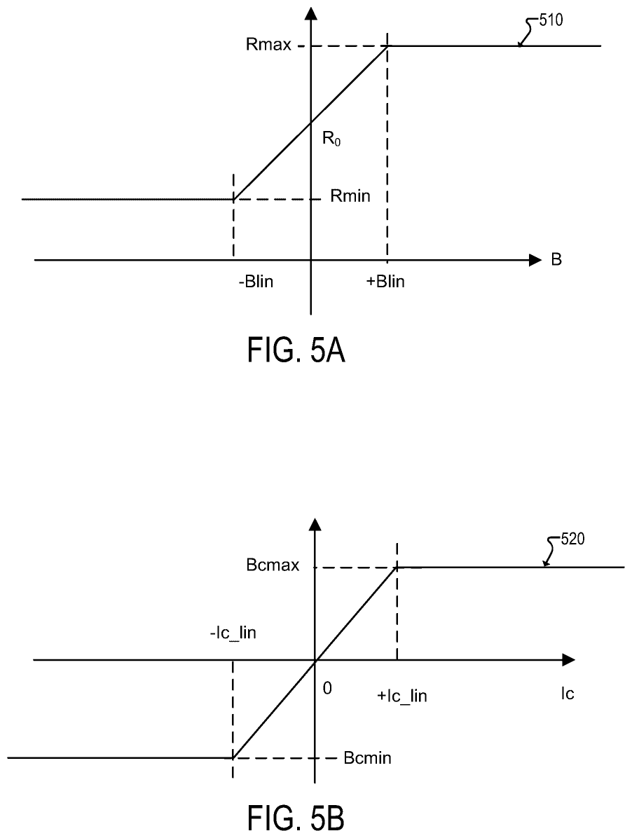

FIG. 5A is a graph of a response curve 510, which illustrates the response of any of the sensing elements (e.g., sensing elements 101, 102, 103, and 104) that form sensing bridge 100. The Y-axis of the graph corresponds to the resistance of the sensing element, and the X-axis of the graph corresponds to the magnetic field that is incident on the sensing element. Curve 510 shows that the resistance of the sensing elements may vary between a value Rmin and a value Rmax. When the value of the magnetic field that is incident on the sensing element is less than or equal to a value −Blin, the resistance of the sensing element is Rmin. When the value of the magnetic field is greater than or equal to +Blin, the resistance of the sensing element is Rmax. When the magnitude of the magnetic field is between-Blin and +Blin, the resistance of the sensing element varies linearly in proportion to the magnitude of the magnetic field.

FIG. 5B is a graph of a response curve 520, which illustrates the response of the feedback coil 410. The Y-axis of the graph corresponds to the magnitude of the feedback magnetic field Bc that is generated by feedback coil 410, and the X-axis of the graph corresponds to the level of the electrical current Ic which is flowing through feedback coil 410. The curve 520 shows that the magnitude of magnetic field Bc may vary between a value Bcmin and a value Bcmax. When the level of the electrical current Ic is less than or equal to a value −Ic_lin, the magnitude of the magnetic field Bc may be Bcmin. When the value of the electrical current Ic is greater than or equal to +Ic_lin, the magnitude of magnetic field Bc is Bcmax. When the level of the electrical current Ic is between −Ic_lin and +Ic_lin, the magnitude of magnetic field Bc varies linearly in proportion to the level of the electrical current Ic.

The operation of the system shown in FIG. 4A is now described in further detail. As illustrated, the current IP, which is measured with sensing bridge 100, may flow through the conductor 130. The feedback coil 410 may generate a field+/−Bc on the sensing bridge 100, as a result of the current Ic. The electrical current Ic through the feedback coil 410 may be arranged to cancel out the output of sensing bridge 100 and ideally cause the signal Vbridge to have the value of ‘0’. A signal Vout may be used to measure the level of the electrical current Ic, which is flowing through the feedback coil 410. The value of signal Vout may be obtained by using resistor Rb (shown in FIG. 4A). The signal Vout may be high-pass filtered to remove any DC component that might be present in it.

A mathematical model is now provided that at least partially describes the operation of sensor 430. The model uses the following quantity definitions (which apply throughout the entire disclosure, unless stated otherwise) and assumptions:
The sensing elements in sensing bridge 100 behave in the manner discussed above with respect to FIG. 5A;
The feedback coil 410 behaves in the manner discussed above with respect to FIG. 5B;
Bs is a stray field, equally applied to legs 105 and 107 of sensing bridge 100;
B1 is the magnetic field applied on resistors 101 and 103 of sensing bridge 100 by electrical current Ip (and conductor 130) (E.g., see FIGS. 3A-B, etc.);
B2 is the magnetic field applied on resistors 102 and 104 of sensing bridge 100 by electrical current Ip (and conductor 130) (E.g., see FIGS. 3A-B, etc.);
R1 is the individual respective resistance of each of sensing elements 101 and 103, of sensing bridge 100 in any of the configurations shown in FIGS. 1A-3A;
R2 is the individual respective resistance of each of sensing elements 102 and 104, of sensing bridge 100 in any of the configurations shown in FIGS. 1A-3A;
Bc is the feedback magnetic field that is created by feedback coil 410;
R₀₁ is the respective individual resistance of each of sensing elements 101 or 103 of sensing bridge 100 when no magnetic field is being applied on sensing elements 101 and 103;
R₀₂ is the respective individual resistance of each of sensing elements 102 or 104 of sensing bridge 100 when no magnetic field is being applied on sensing elements 102 or 104;
R₀=(R₀₁+R₀₂)/2.
Rₘₐₓ₁ is the maximum individual resistance of each of sensing elements 101 or 103 of sensing bridge 100;
Rₘₐₓ₂ is the maximum individual resistance of each of sensing elements 102 or 104 of sensing bridge 100;
Rₘᵢₙ₁ is the minimum individual resistance of each of sensing elements 101 or 103 of sensing bridge 100;
Rₘᵢₙ₂ is the minimum individual resistance of each of sensing elements 102 or 104 of sensing bridge 100;
S is the sensitivity of sensing bridge 100;
V_{IN} is the bridge input voltage
The sensing elements that form sensing bridge 100 (e.g., sensing elements 101, 102, 103, and 104) are operated in their linear range (i.e., −Blin<|B1+Bs+Bc|<Blin && −Blin<|B₂+Bₛ−B_{c}|<Blin).

According to the model, the bridge output Vbridge may be described by equations 1 and 2 below:

$$if \vert {B}_{1} + {B}_{s} + {B}_{c} \vert < {B}_{lin} \qquad ( Equation 1 )$$

$$and$$

$$\vert {B}_{2} + {B}_{s} - {B}_{c} \vert < {B}_{lin}$$

$$then$$

$${V}_{bridge} = ( {R}_{01} ( 1 + S . ( {B}_{1} + {B}_{s} + {B}_{c} ) ) - {R}_{02} ( 1 + S . ( {B}_{2} + {B}_{s} - {B}_{c} ) ) ) \cdot \frac{{V}_{IN}}{2 {R}_{0}}$$

$$if {B}_{1} + {B}_{s} + {B}_{c} \geq {B}_{lin} \qquad ( Equation 2 )$$

$$and$$

$${B}_{2} + {B}_{s} - {B}_{c} \geq {B}_{lin}$$

$$then$$

$${V}_{bridge} = \frac{{R}_{max 1} - {R}_{max 2}}{{R}_{max 1} + {R}_{max 2}} \cdot {V}_{IN}$$

$$elseif {B}_{1} + {B}_{s} + {B}_{c} \leq - {B}_{lin}$$

$$and$$

$${B}_{2} + {B}_{s} - {B}_{c} \leq - {B}_{lin}$$

$$then$$

$${V}_{bridge} = \frac{{R}_{min 1} - {R}_{min 2}}{{R}_{min 1} + {R}_{min 2}} \cdot {V}_{IN}$$

In the context of the above model, and/or FIGS. 1A-5, several methods are now described for detecting when sensor 430 is subject to tampering. These methods are enumerated as Methods 1 through 4.

### Method 1

Method 1 depends on comparing the output Vbridge of sensing bridge 100 and the feedback current Ic to a predetermined threshold. It will be recalled that the feedback current Ic is the electrical current used to drive feedback coil 410 (shown in FIG. 4A). In Method 1, the value of signal Vout is used as a proxy for the level of the electrical current Ic.

According to Equation 1, small stray fields, typically |Bs|<Blin, are naturally rejected due to differential sensing and AC coupling removing at least some of the offset that is created by the stray fields. With high stray fields (typically stray fields resulting from a tampering attempt), |Bs|>Blin, the output of sensing bridge 100 is given by Equation 2. In this case, all sensing elements that form sensing bridge 100 (e.g., sensing elements 101, 102, 103, and 104) will be saturated. In this scenario, and with reference to FIGS. 5A-B, the magnetic feedback loop, which is implemented using feedback coil 410 and driver 412 (shown in FIG. 4A), will diverge to saturation, either to +Ic_lin or to −Ic_lin (depending on the sign of Vbridge), while trying to make Vbridge equal to zero. In other words, when the sensing elements that form sensing bridge 100 are saturated, the value of the feedback current Ic would either become greater than or equal to +Ic_lin or less than or equal to −Ic_lin.

A threshold V_{T1} on signal Vout may be used to detect feedback coil saturation. For example, the threshold V_{T1} may be defined as follows: V_{T1}=Rb.Ic_max−ε₁, where ε₁ is an arbitrarily small number, and Rb is the resistance of resistor Rb (shown in FIG. 4B). If |Vout|>V_{T1}, then the feedback coil is saturated.

A threshold V_{T2} on signal Vbridge may be used to detect if the magnetic feedback loop (implemented by using feedback coil 410 and driver 412) is nullifying the output of sensing bridge 100. The threshold V_{T2} may be defined in accordance with equation 3 below. Alternatively, the threshold V_{T2} may be specified in the factory, during end-of-line calibration. Specifically, during end-of-line calibration, the offset of sensing bridge 100 may be measured, in a positive and negative high magnetic field Bcal (for example Bcal>2*Bₗᵢₙ), and the threshold V_{T2} may be set to a multiple of the offset that is present in the output Vbridge of sensing bridge 100 while the calibration magnetic field Bcal is being applied. For example, the threshold V_{T2} may be set to twice the offset, five times the offset, ten times the offset, etc. Alternatively, the value of threshold V_{T2} may be determined once for all sensors (rather than being determined individually for each sensor during calibration) based on knowledge of the tolerances in the fabrication process that is used. Particularly, if |Vbridge|<V_{T2}, then the feedback coil is properly canceling the bridge output.

$${V}_{T 2} = k \times {V}_{IN} \times max ( \vert \frac{{R}_{max 1} - {R}_{max 2}}{{R}_{max 1} + {R}_{max 2}} \vert , \vert \frac{{R}_{min 1} - {R}_{min 2}}{{R}_{min 1} + {R}_{min 2}} \vert ) \qquad Equation 3$$

In some respects, equation 3 indicates that the threshold is based on k times the remaining offset voltage of the bridge when fully-saturated, in one or the other direction.

In the case of an out-of-specification, high primary current Ip, |Vout|>V_{T1} because the feedback current Ic would be saturated. At the same time, |Vbridge|>V_{T2}, because the magnetic feedback loop would no longer be able to cancel out the output of sensing bridge 100. In this case, the bridge voltage is given by Equation 4 below. In this example, Equation 4 assumes that no stray field is present.

$$( Equation 4 )$$

$${V}_{bridge} = ( {R}_{01} ( 1 + S . ( {B}_{1} + {B}_{c \_ max} ) ) - {R}_{02} ( 1 + S . ( {B}_{2} - {B}_{c \_ max} ) ) ) . \frac{{V}_{IN}}{2 {R}_{0}}$$

In view of the foregoing, the following truth table (Table 1) may be devised, which can be employed by sensor 430 to detect various errors.

TABLE 1

| \|Vout\| > V_{T1} | \|Vbridge\| > V_{T2} | |
|---|---|---|
| (Is the feedback coil | (Is the bridge output | |
| saturated?) | different from zero?) | Status |
| 1 | 0 | Tampering Condition |
| 0 | 0 | Normal Operation |
| 1 | 1 | Over-current Condition |
| 0 | 1 | Failed Feedback Loop |

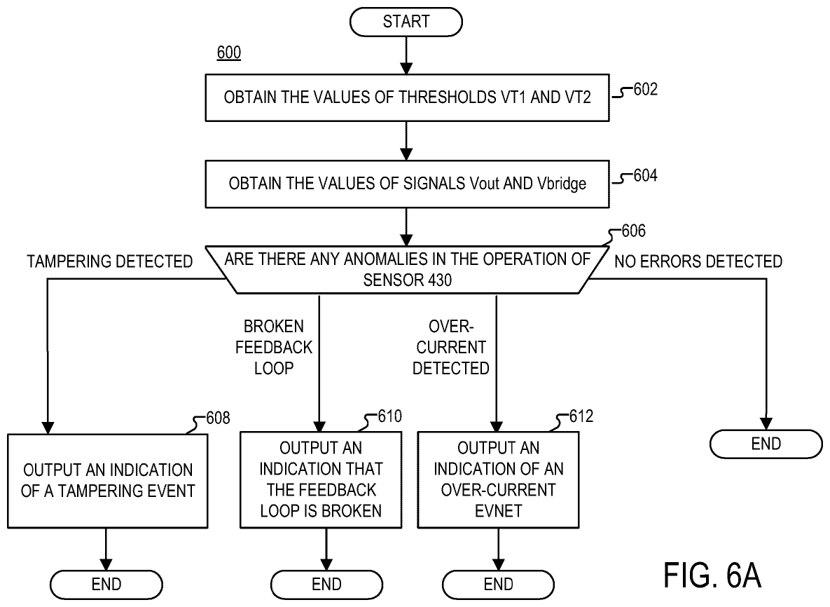

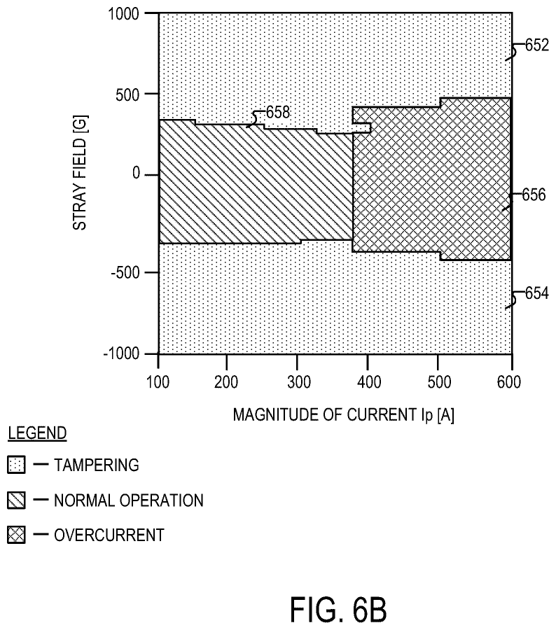

FIG. 6A is a flowchart of an example of a process 600, which implements Method 1, according to aspects of the disclosure. According to the present example, process 600 is performed by processing circuitry 440 of sensor 430. However, the present disclosure is not limited to any specific entity or set of entities performing the process 600. As is discussed further below, process 600 implements the rules that are shown in Table 1.

At step 602, processing circuitry 440 determines the values of thresholds V_{T1} and V_{T2}. At step 604, processing circuitry 440 determines the values of signals Vout and Vbridge. At step 606, processing circuitry 440 compares thresholds V_{T1} and V_{T2} to the absolute values of signals Vout and Vbridge, respectively. The purpose of the comparison is to determine if there are any anomalies in the operation of sensor 430. The comparison is performed in accordance with the truth table above (i.e., Table 1). Specifically, if the absolute value of signal Vout is greater than threshold V_{T1} and the absolute value of signal Vbridge is not greater than threshold V_{T2}, processing circuitry 440 determines that sensor 430 is subject to a tampering event, and process 600 proceeds to step 608. If the absolute value of signal Vout is not greater than threshold V_{T1} and the absolute value of signal Vbridge is greater than threshold V_{T2}, processing circuitry 440 determines that feedback loop 436 has failed, and process 600 proceeds to step 610. If the absolute value of signal Vout is greater than threshold V_{T1} and the absolute value of signal Vbridge is greater than threshold V_{T2}, processing circuitry 440 determines sensor 430 is subject to an overcurrent event, and process 600 proceeds to step 612. If the absolute value of signal Vout is not greater than threshold V_{T1} and the absolute value of signal Vbridge is not greater than threshold V_{T2}, processing circuitry 440 determines that no anomalies are present in the operation of sensor 430 and process 600 ends.

At step 608, processing circuitry 440 outputs an indication that sensor 430 is subject to a tampering event. According to the present example, signal 444 is set to ‘1’. However, the present disclosure is not limited to outputting any specific type of indication. At step 610, processing circuitry 440 outputs an indication that the feedback loop of sensor 430 has failed. According to the present example, signal 448 is set to ‘1’. However, the present disclosure is not limited to any specific type of indication. At step 612, processing circuitry 440 outputs an indication that sensor 430 is subject to an over-current event. According to the present example, signal 446 is set to ‘1’. However, the present disclosure is not limited to outputting any specific type of indication.

For the purposes of Method 1, the sensing bridge 100 can be replaced by any differential magnetic sensing module, such as a sensing module that uses Hall elements or fluxgates, and which has a profile like the one illustrated in FIG. 5A. For example, fluxgate range can be adjusted accordingly by tuning the core and coil designs and with associated electronics. For Hall elements, some clamps on the output can be set electronically or the saturation of the associated ADC can be used as well. In the very unlikely cases of Rₘₐₓ₁=Rₘₐₓ₂ or Rₘᵢₙ₁=Rₘᵢₙ₂, then the close loop will not diverge in case of tampering, meaning Vbridge=Vout=0. To overcome this potential issue, an artificial small current pulse can be periodically, or permanently, added to the amplifier output, while the closed-loop behavior is observed. If the pulse is detected on the feedback coil, it means tampering is happening. By contrast, during regular operation, the loop works to cancel out the injected pulse. It should be noted that in the case of an AC primary current at frequency fp, it is enough to meet Table 1 conditions once over one period (1/fp) to trigger an error.

FIG. 6B is a plot of the stray field that is incident on sensor 430 versus the magnitude of the primary current Ip that flows through conductor 130. Regions 652 and 654 correspond to a state in which sensor 430 is subject to a tampering condition. Region 656 corresponds to a state in which sensor 430 is subject to an overcurrent condition. And region 658 corresponds to a state in which sensor 430 is operating normally.

FIG. 7 is a schematic diagram of an example of a sensing circuit 700, which can be used in one of the implementations of Method 2, which is discussed further below. Shown in FIG. 7 are sensing elements 701 and 702, which are used to generate a differential signal Vₛₑ. The respective outputs of sensing elements are defined by equations 5 and 6 below, which assume linear output with saturation:

$${V}_{se 1} = k \times {B}_{1} for \vert {B}_{1} \vert < {B}_{lin} , else {V}_{se 1} = \pm {V}_{max} \qquad ( Equation 5 )$$

$${V}_{se 2} = k \times {B}_{2} for \vert {B}_{2} \vert < {B}_{lin} , else {V}_{se 2} = \pm {V}_{max} \qquad ( Equation 6 )$$

$${B}_{1} = {CF}_{1} \times Ip \qquad ( Equation 7 )$$

$${B}_{2} = {CF}_{2} \times Ip \qquad ( Equation 8 )$$

Where, Vₛₑ₁ is the output of sensing element 701, Vₛₑ₂ is the output of sensing element 702, k is the sensitivity of the sensing element, and CF₁ and CF₂ are the coupling factors, B₁ is the magnetic field at the location of sensing element 701, B₂ is the magnetic field at the location of sensing element 702, Blin is the magnetic field limit of the linear range of each of sensing elements 701 and 702, and Vmax, is the maximum voltage that can be output by any one of sensing elements 701 and 702, which sits at the end of the linear range of sensing elements 701 and 702. In this example, CF₁ and CF₂ have opposite signs.

The linear range of sensing elements 701 and 702 is shown in FIG. 8. FIG. 8 shows an example of a response curve 810 which illustrates the response of sensing elements 701 and 702. The Y-axis of the graph corresponds to the voltage that is output by any one of sensing elements 701 and 702 (e.g., it corresponds to the value of either one of signals Vₛₑ₁ and Vₛₑ₂), and the X-axis of the graph corresponds to the magnetic field that is incident on the sensing element. Response curve 810 shows that the output of each of sensing elements 701 or 702 may vary between values Vmin and Vmax. When the value of the magnetic field that is incident on sensing elements 701 and 702 is less than or equal to a value −Blin, the output voltage of each of sensing elements 701 and 702 is Vmin. When the value of the magnetic field is greater than or equal to +Blin, the output voltage of each of sensing elements 701 and 702 is Vmax. When the magnitude of the magnetic field is between-Blin and +Blin, the output voltage of each of sensing elements 701 and 702 varies linearly in proportion to the magnitude of the magnetic field.

In some implementations, each of sensing elements 701 and 702 may include a Hall element (e.g., vertical or planar), a magnetoresistive (MR) element (e.g., a TMR, a GMR, etc.), a half-bridge that is formed of MR elements, a full-bridge circuit that is formed of MR elements, and/or any other suitable type of MR element.

### Method 2

Method 2 detects tampering by examining the saturation states of different sensing elements in the sensing module 432 (shown in FIG. 4B). Method 2 works when sensor 430 is arranged in an open-loop or closed-loop configuration. All implementations of Method 2 can be performed by processing circuitry 440 of sensor 430 (shown in FIG. 4B) to detect the presence of a tampering condition. All implementations of method 2 may be performed based on the output of different sensing elements that form sensing module 432. Method 2 assumes that that the coupling coefficients CF₁ and CF₂ have opposite signs.

A first implementation of Method 2 is now described as follows. The first implementation of Method 2 assumes that the sensing module 432 is implemented as the sensing circuit 700 (shown in FIG. 7). The first implementation of Method 2 is valid if the sensing elements se1 and se2 are only sensitive to one direction of the magnetic field. For example, sensing elements se1 and se2 may be sensitive to only one magnetic field direction when they are implemented by using planar or vertical Hall elements.

According to the first implementation of Method 2, threshold T21, T22, T23, and T24 are defined, where T21=Vₘₐₓ₁−ε, T22=−Vₘₐₓ₂+ε, T23=Vₘᵢₙ₁−ε, and T24=−Vₘᵢₙ₁+ε and ε is a constant. In this example, Vₘₐₓ₁ is the maximum value of signal Vₛₑ₁, Vₘₐₓ₂ is the maximum value of signal Vₛₑ₂, Vₘᵢₙ₁ is the minimum value of signal Vₛₑ₁, and Vₘᵢₙ₂ is the minimum value of signal Vₛₑ₂, and ε is a constant (e.g., a constant that is determined depending on the application and which is equal to a small fraction of the maximum or minimum value of any of signals Vₛₑ₁ and Vₛₑ₂). Furthermore, according to the example below, tampering conditions M21 and M22 are defined, which are shown in Table 2 below. Tampering conditions M21 and M22 depend on comparing signal Vse1 against thresholds T21 and T22, and comparing signal Vₛₑ₂ against thresholds T23 and T24. According to this example, tampering condition M21 is satisfied when: signal Vₛₑ₁ is greater than threshold T21 and greater than or equal to threshold T22, while signal Vₛₑ₂ is greater than threshold T23 and greater than or equal to threshold T24. Tampering condition M22 is satisfied when signal Vse1 is less than or equal to threshold T21 and less than threshold T22, while signal Vse2 is less than or equal to threshold T23 and less than threshold T24.

TABLE 2

| | Vₛₑ₁ > | Vₛₑ₁ < | Vₛₑ₂ > | Vₛₑ₂ < | |
|---|---|---|---|---|---|
| , # | T21 | T22 | T23 | T24 | Status |
| M21 | 1 | 0 | 1 | 0 | Tampering |
| M22 | 0 | 1 | 0 | 1 | Tampering |

In operation, processing circuitry 440 (shown in FIG. 4B) may retrieve from memory the values of thresholds T21, T22, T23, and T24. Next, processing circuitry 440 may obtain the values of signals Vse1 and Vse2. Next, processing circuitry 440 may compare signal Vse against thresholds T21 and T22. Next, processing circuitry 440 may compare signal Vₛₑ₂ against thresholds T23 and T24. Next, processing circuitry 440 may determine, based on the outcome of the comparisons, whether condition M21 and/or condition M22 are satisfied. And finally, if any of conditions M21 and M22 are satisfied, processing circuitry 440 may output an indication that sensor 430 is subject to a tampering event. The indication may be output in the manner discussed above with respect to step 608 (shown in FIG. 6A).

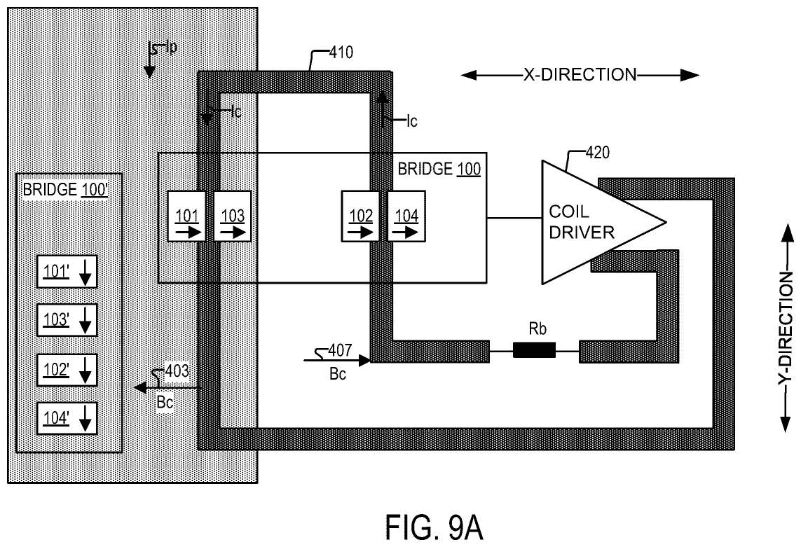

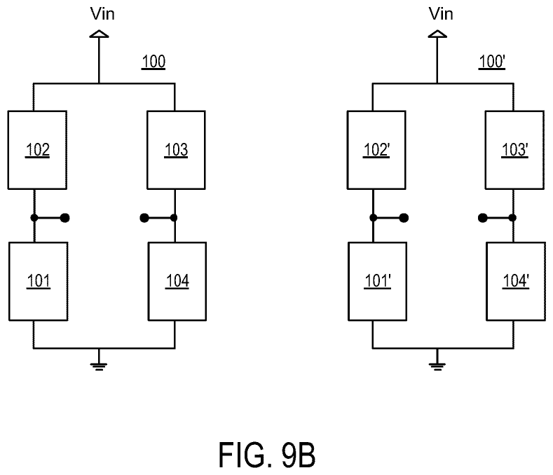

A second implementation of Method 2 is now described in further detail. The second implementation of Method 2 assumes that the sensing module 432 is implemented in the manner discussed further below with respect to FIG. 9A. In the second implementation of Method 2, the sensing elements in module 432 are sensitive in two directions.

FIG. 9A shows an example of a system that is identical to the system of FIG. 4A, but for including the sensing bridge 100′. In the example of FIG. 9A, the sensing bridge 100′ is configured in the same manner as sensing bridge 100. In the example of FIG. 9, sensing bridge 100′ is operated separately of sensing bridge 100 (i.e., it is not connected in parallel to sensing bridge 100 as is the case with the example of FIG. 3B.)

Sensing bridge 100′ may include sensing elements 101′, 102′, 103′, and 104′ that are coupled to each other in the manner shown in FIG. 9A. The axis of maximum sensitivity of sensing element 101′ may be arranged at approximately 90° relative to the axis of maximum sensitivity of sensing element 101. The axis of maximum sensitivity of sensing element 102′ may be arranged at approximately 90° relative to the axis of maximum sensitivity of sensing element 102. The axis of maximum sensitivity of sensing element 103′ may be arranged at approximately 90° relative to the axis of maximum sensitivity of sensing element 103. The axis of maximum sensitivity of sensing element 104′ may be arranged at approximately 90° relative to the axis of maximum sensitivity of sensing element 104. The phrase “approximately 90 degrees” shall mean within “+/−10 degrees of being exactly 90 degrees.”

Moreover, sensing bridge 100′ is rotated by approximately 90°, relative to sensing bridge 100. Specifically, the sensing elements that form sensing bridge 100′ (e.g., sensing elements 101′, 102′, 103′, and 104′) are disposed over conductor 130, and distributed in the Y-direction, while the sensing elements that form sensing bridge 100 are distributed in the X-direction. As a result of this configuration, the sensing elements that form sensing bridge 100′ see the same magnetic field and the output of sensing bridge 100′ would be zero under normal operating conditions. As used herein, the phrase “approximately 90°” means “within +/−10% of being exactly 90 degrees”.

In the example of FIG. 9A, the direction, relative to conductor 130 and coil 410, of the respective axis of maximum sensitivity of each sensing element 101, 102, 103, 104, 101′, 102′, 103′, and 104′ is indicated by the arrow inside the rectangle representing the sensing element. However, the present disclosure is not limited to sensing elements 101, 102, 103, 104, 101′, 102′, 103′, and 104′ having any specific axis of maximum sensitivity.

The second implementation of Method 2 requires sensing elements 101, 102, 103, 104, 101′, 102′, 103′, and 104′ to be magnetoresistors, such as giant magnetoresistance (GMR) elements or tunneling magnetoresistance (TMR) elements or anisotropic magnetoresistance (AMR). In the example of FIG. 9A, each of sensing elements 101, 102, 103, 104, 101′, 102′, 103′, and 104′ has a minimum resistance Rmin and a maximum resistance Rmax. FIG. 9B shows the respective topologies of sensing bridges 100 and 100′. FIG. 9B is provided to compare sensing bridge 100 to sensing bridge 100′ and illustrate that sensing bridge 100′ may have the same topology as sensing bridge 100. As noted above, in the example of FIG. 9A, sensing bridge 100 is also arranged in the manner discussed with respect to FIG. 4A.

According to the second implementation of Method 2, thresholds T25, T26, T27, T28, T25′, T26′, T27′, and T28′, are defined as follows: T25=Rₘₐₓ₁−ε, T26=Rₘᵢₙ₁+ε, T27=Rₘₐₓ₂−ε, T28=Rₘᵢₙ₂+ε, T25′=R′ₘₐₓ₁−ε, T26′=R′ₘᵢₙ₁+ε, T27′=R′ₘₐₓ₂−ε, and T28′=R′ₘᵢₙ₂+ε. According to the present example, Rₘₐₓ₁ is the respective saturation resistance of at least one of sensing elements 101 and 103, Rmin is the respective minimum resistance of at least one of sensing elements 101 and 103, Rₘₐₓ₂ is the respective maximum resistance of at least one of sensing elements 102 and 104, and Rₘᵢₙ₂ is the respective minimum resistance of at least one of sensing elements 102 and 104. According to the present example, R′ₘₐₓ₁ is the respective saturation resistance of at least one of sensing elements 101′ and 103′, R′ₘᵢₙ₁ is the respective minimum resistance of at least one of sensing elements 101′ and 103′, R′ₘₐₓ₂ is the respective maximum resistance of at least one of sensing elements 102′ and 104′, and R′ₘᵢₙ₂ is the respective minimum resistance of at least one of sensing elements 102′ and 104′. Rₘₐₓ is the respective saturation resistance (or maximum resistance) of each (or at least one) of sensing elements 101, 102, 103, 104, and Rmin is the respective minimum resistance of each (or at least one) of sensing elements 101, 102, 103, 104, R′ₘₐₓ is the respective saturation resistance (or maximum resistance) of each (or at least one) of sensing elements 101′, 102′, 103′, and 104′, and R′ₘᵢₙ is the respective minimum resistance of each (or at least one) of sensing elements 101′, 102′, 103′, and 104′. R1 is the respective instant resistance of each (or at least one) of sensing elements 101 and 103, R2 is the respective instant resistance of each (or at least one) of sensing elements 102 and 104, R1′ is the respective instantaneous resistance of each (or at least one) of sensing elements 101′ and 103′, and R2′ is the respective instant resistance of each of each (or at least one) sensing elements 102′ and 104′. The term “instant resistance” refers to the resistance that is assumed by a sensing element at a given moment in response to the magnetic field which the sensing element is being subjected to at this moment.

Condition M23 may be satisfied when: resistance R1 is greater than threshold T25, resistance R1 is greater than or equal to threshold T26, resistance R2 is greater than threshold T27, and resistance R2 is greater than or equal to threshold T28. Condition M24 may be satisfied when: resistance R1 is less than or equal to threshold T25, resistance R1 is less than threshold T26, resistance R2 is less than or equal to threshold T27, and resistance R2 is less than threshold T28. Condition M25 may be satisfied when: resistance R1′ is greater than threshold T25′, resistance R1′ is greater than or equal to threshold T26′, resistance R2′ is greater than threshold T27′, and resistance R2′ is greater than or equal to threshold T28′. Condition M26 may be satisfied when: resistance R1′ is less than or equal to threshold T25, resistance R1′ is less than threshold T26′, resistance R2 ‘is less than or equal to threshold T27’, and resistance R2′ is less than threshold T28′. If any of conditions M23-M26 is satisfied, this may indicate the presence of a tampering condition.

TABLE 3

| ID | R1 > T25 | R1 < T26 | R2 > T27 | R2 < T28 | Status |
|---|---|---|---|---|---|
| M23 | 1 | 0 | 1 | 0 | Tampering |
| M24 | 0 | 1 | 0 | 1 | Tampering |

TABLE 4

| # | R1′ > T25′ | R1′ < T26′ | R2′ > T27′ | R2′ < T28′ | Status |
|---|---|---|---|---|---|
| M25 | 1 | 0 | 1 | 0 | Tampering |
| M26 | 0 | 1 | 0 | 1 | Tampering |

In operation, processing circuitry 440 (shown in FIG. 4B) may retrieve from memory the values of thresholds T25, T26, T27, T28, T25′, T26′, T27′, and T28. Next, processing circuitry 440 may measure the resistances R1 and R2. Next, processing circuitry 440 may compare resistance R1 against thresholds T24 and T26. Next, processing circuitry 440 may compare resistance R2 against thresholds T27 and T28. Next, processing circuitry 440 may measure the resistances R1′ and R2′. Next, processing circuitry 440 may compare resistance R1′ against thresholds T24′ and T26′. Next, processing circuitry 440 may compare resistance R2′ against thresholds T27′ and T28′. Next, processing circuitry 440 may determine, based on the outcome of the comparisons, whether at least one (or each) of conditions M23, M24, M25, and M26 are satisfied. And finally, if any of conditions M23, M24, M25, and M26 are satisfied, processing circuitry 440 may output an indication that sensor 430 is subject to a tampering event. The indication may be output in the manner discussed above with respect to step 608 (shown in FIG. 6A).

A third implementation of Method 2 is now described in further detail. The third implementation of Method 2 assumes that the sensing module 432 is implemented in the manner discussed above with respect to FIG. 9A. According to the third implementation of Method 2, the equivalent resistance Req of sensing bridge 100 and the equivalent resistance Req′ of sensing bridge 100′ are compared against thresholds T29, T30, T31, and T32. Thresholds T29, T30, T31, and T32 are defined as follows: T29=Rₘₐₓ−ε, T30=Rₘᵢₙ+Σ, T31=Rₘₐₓ−ε, T32=Rₘᵢₙ+ε, where ε and Rmax is the saturation resistance of sensing bridges 100 and 100′, Rmin is the minimum resistance of sensing bridges 100 and 100′, and & is a constant. Conditions M27, M28, and M29, and M30 are defined as illustrated in Table 5, below. As illustrated, conditions M27-M30 are defined in terms of the equivalent resistance Req of sensing bridge 100 and the equivalent resistance Req′ of sensing bridge 100′. From FIG. 1C, Req=Vin*Ref/(Vin−V2), with Ref being the resistance of resistor 115. For ease of description, the present example assumes that sensing bridges 100 and 100′ have the same minimum and maximum resistance. However, in some implementations, each of the thresholds T29-T32 may be based on the minimum or maximum resistance of the sensing bridge that generates the signal that is being compared against the threshold. For example, threshold T29 may be based on the maximum resistance of sensing bridge 100; threshold T30 may be based on the minimum resistance of sensing bridge 100; threshold T31 may be based on the maximum resistance of sensing bridge 100′; and threshold T32 may be based on the minimum resistance of sensing bridge 100′.

Condition M27 may be satisfied when: resistance Req is greater than threshold T29, resistance Req is greater than or equal to threshold T30, resistance Req′ is less than or equal to threshold T31, and resistance Req′ is greater than or equal to threshold T32. Condition M28 may be satisfied when: resistance Req is less than or equal to threshold T29, resistance Req is less than threshold T30, resistance Req′ is less than or equal to threshold T31, and resistance Req′ is greater than or equal to threshold T32. Condition M29 may be satisfied when: resistance Req is less than or equal to threshold T29, resistance Req is greater than or equal to threshold T30, resistance Req′ is greater than threshold T31, and resistance Req′ is greater than or equal to threshold T32. Condition M30 may be satisfied when: resistance Req is less than or equal to threshold T29, resistance Req is greater than or equal to threshold T30, resistance Req′ is less than or equal to threshold T31, and resistance Req′ is less than threshold T32. If any of conditions M29-M32 is satisfied, this may indicate the presence of a tampering condition.

TABLE 5

| ID | R_{eq} > T29 | R_{eq} < T30 | R_{eq}′ > T31 | R_{eq}′ < T32 | Status |
|---|---|---|---|---|---|
| M27 | 1 | 0 | 0 | 0 | Tampering |
| M28 | 0 | 1 | 0 | 0 | Tampering |
| M29 | 0 | 0 | 1 | 0 | Tampering |
| M30 | 0 | 0 | 0 | 1 | Tampering |

In operation, processing circuitry 440 (shown in FIG. 4B) may retrieve from memory the values of thresholds T29, T30, T31, and T32. Next, processing circuitry 440 may determine the resistances Req and Req′. Next, processing circuitry 440 may compare resistance Req against thresholds T29 and T30. Next, processing circuitry 440 may compare the resistance Req′ against thresholds T31 and T32. Next, processing circuitry 440 may determine, based on the outcome of the comparisons, whether at least one (or each) of conditions M27, M28, M29, and M30 are satisfied. And finally, if any of conditions M27, M28, M29, and M30 are satisfied, processing circuitry 440 may output an indication that sensor 430 is subject to a tampering event. The indication may be output in the manner discussed above with respect to step 608 (shown in FIG. 6A).

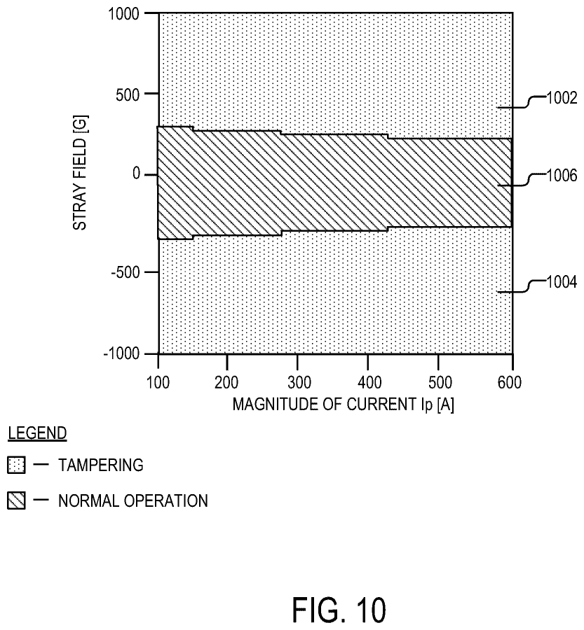

FIG. 10 is a plot of the stray field that is incident on sensor 430 versus the magnitude of the primary current Ip that flows through conductor 130. Regions 1002 and 1004 correspond to a state in which sensor 430 is subject to a tampering event. And region 1006 corresponds to a state in which sensor 430 is operating normally.

As used throughout the disclosure, when permitted by context, the term “sensing element” may refer to one of: (i) one or more magnetoresistors (or other magnetic field sensing elements, such as Hall elements or fluxgate elements), (ii) a leg in a sensing bridge, such as legs 105 and 107 (shown in FIG. 1A), or (iii) an entire sensing bridge. In the example of Tables 2-5, the output of a sensing element is compared against a threshold that is based on either a minimum or maximum resistance of the sensing element. In the example of Tables 2-5 all sensing elements are presumed to have the same minimum and maximum resistance. However, in alternative implementations, different sensing elements may have different maximum or minimum resistances. In such implementations, the signal that is generated by a sensing element (or the resistance of the sensing element) would be compared against a threshold that is calculated based on the minimum or maximum resistance of the sensing element. For instance, in the example of Table 2, signal Vse1 may be compared against thresholds that are calculated based on the minimum and maximum resistance of the sensing element that generated signal Vse1 (i.e., sensing element se1) and signal Vse2 may be compared against thresholds that are calculated based on the minimum and maximum resistance of the sensing element that generated signal Vse2 (i.e., sensing element se2). Similarly, in the example of Table 3, the resistance R1 may be compared against thresholds that are calculated based on the minimum and maximum resistance of the sensing element that corresponds to resistance R1 (i.e., sensing elements 101 and 103) and the resistance R2 may be compared against thresholds that are calculated based on the minimum and maximum resistance of the sensing element that corresponds to resistance R2 (i.e., sensing elements 102 and 104).

### Method 3

Method 3 detects tampering by monitoring the sensitivity of sensor 430. Normally, sensor 430 may have one sensitivity when it is not subject to tampering. However, when sensor 430 is subjected to tampering its sensitivity may be greatly reduced (or completely extinguished in the extreme case). So, to detect tampering, Method 3 compares the sensitivity of sensor 430 against a threshold. If the sensitivity is above a threshold, a determination may be made that no tampering is present. On the other hand, if the sensitivity is below the threshold, it may be determined that sensor 430 is subject to a tampering condition.

Method 3, in this example, assumes that sensing module 432 is the same as sensing bridge 100. Furthermore, Method 3 assumes that sensing bridge has the configuration shown in FIG. 1. However, in alternative implementations sensing module 432 may be the same as sensing module 120 (shown in FIG. 1D) or the same as magnetometer 150. Method 3 uses coil 410 to monitor the sensitivity of sensing module 432. However, in the example of Method 3, coil 410 need not be driven based on the output of sensing bridge 100. For example, coil 410 may be driven independently of the output of sensing bridge 100. Irrespective of whether coil 410 is used to implement a magnetic feedback loop or not, coil 410 may be driven with an electrical current that has a frequency fs, which is sufficiently greater than the frequency fp of the primary current Ip. Driving the coil 410 in this manner causes the coil 410 to generate a reference magnetic field that has the frequency fs. The response of sensing module 432 to the reference magnetic field is obtained by running the signal Vbridge through a high pass filter, or band-pass filter, to obtain a filtered signal Vbridge. Next, the sensitivity of the sensing module 432 is determined based on the filtered signal Vbridge. Next, the sensitivity of the sensing module 432 is compared against a threshold by processing circuitry 440. If the sensitivity of the signal Vbridge is above a threshold, processing circuitry 440 may determine that sensor 430 is not subject to tampering. On the other hand, if the sensitivity is below a threshold, processing circuitry 440 may determine that sensor 430 is being tampered with.

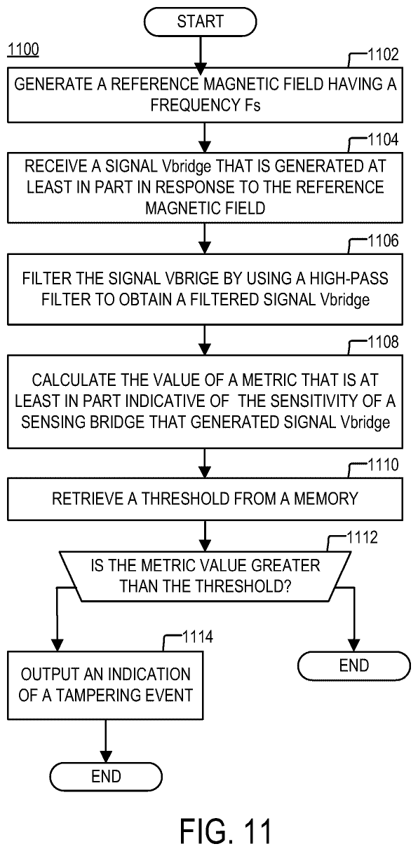

FIG. 11 is a flowchart of an example of a process 1100 which implements Method 3, according to aspects of the disclosure. Process 1100 is performed by sensor 430 (and/or processing circuitry 440 of sensor 430). In the example of FIG. 11, sensing module 432 is the same as sensing bridge 100.

At step 1102, a reference magnetic field is generated by using coil 410. The reference magnetic field may have a frequency fs, which is greater than the frequency of the electrical current Ip, which sensor 430 is used to measure. The reference magnetic field may be generated by driving the coil 410 with an electrical current that has the frequency fs.

At step 1104, the value of signal Vbridge is obtained from sensing bridge 100. The signal Vbridge is generated by sensing bridge 100, at least in part, in response to the reference magnetic field.

At step 1106, the signal Vbridge is filtered by using a high-pass filter. The high-pass filter may be configured to block all (or most) frequencies in signal Vbridge that are below the frequency Fs. The high-pass filter may be configured to block all (or some) frequencies in signal Vbridge, which correspond to the frequency of the electrical current Ip. The high-pass filter may be configured to let through all (or some) frequencies that correspond to the reference magnetic field. The high-pass filtered may output a filtered signal Vbridge.

At step 1108, the value of a metric is calculated that is at least in part indicative of the sensitivity of sensing bridge 100 to the reference magnetic field (generated at step 1102). In some implementations, the metric value may be calculated by determining the ratio between: (i) the voltage level of filtered signal Vbridge and (ii) the level of the electrical current which is used to drive the coil 410. However, it will be understood that the present disclosure is not limited to using any specific metric that is indicative of the sensitivity of sensing bridge 100 to the reference magnetic field.

At step 1110, a threshold is retrieved from a memory of the processing circuitry 440 (e.g., a memory that is integrated into processing circuitry 440 or otherwise accessible to processing circuitry 440). The threshold may have any suitable value. In one example, the threshold may be equal to 50% of the normal sensitivity of sensing bridge 100.

At step 1112, the metric value (determined at step 1108) is compared to the threshold (obtained at step 1110). If the metric value is greater than the threshold, process 1100 ends. Otherwise, if the metric value is less than the threshold, process 1100 proceeds to step 1114.

At step 1114, an indication is output indication that sensor 430 is subject to a tampering event. According to the present example, signal 444 is set to ‘1’. However, the present disclosure is not limited to outputting any specific type of indication.

In the example of FIG. 11, the frequency fs is greater than the frequency fp. However, in alternative implementations, the frequency fs may be smaller than the frequency fp. In such implementations, a low-pass filter may be used instead to filter the output of sensing bridge 100. The low pass filter may be configured to block all frequencies that correspond to the current Ip, while letting through all (or at least some) frequencies that correspond to the reference magnetic field

### Method 4

Method 4 assumes that sensing module 432 is the same as sensing bridge 100 when sensing bridge 100 is arranged in a gradiometer configuration (shown in FIG. 3A). Method 4 is valid only when sensing bridge 100 is implemented with magnetoresistors, such as GMR elements or TMR elements. Method 4 further assumes that conductor 130 is implemented as shown in FIG. 3A. Method 4 involves monitoring the current consumption of sensing bridge 100. In the absence of tampering, the equivalent resistance of sensing bridge 100 will remain in a certain range. In this regard, according to Method 4, sensor 430 (and/or processing circuitry 440) may monitor the current consumption of sensing bridge 100, and determine that sensor 430 is subject to a tampering condition when the current consumption of the sensing bridge 100 is out of bounds. Essentially, Method 4 looks at the total resistance of the sensing bridge 100, and when the total resistance is at (or below) a minimum value or at (or above) a maximum value, Method 4 determines that sensing bridge 100 is subject to a tampering condition.

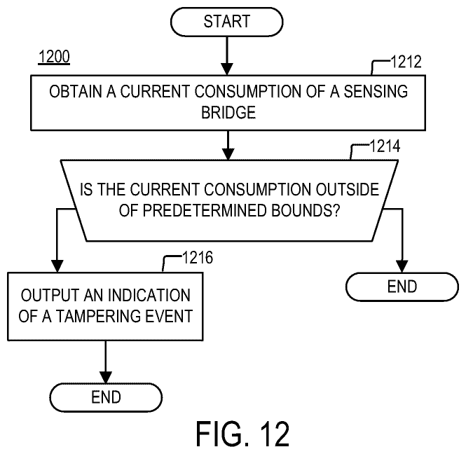

FIG. 12 is a flowchart of an example of a process 1200 which implements Method 4, according to aspects of the disclosure. Process 1200 may be used to detect whether at least one of the magnetoresistors in a gradiometer used to implement sensing module 432 is in a parallel or antiparallel state. Process 1200 is performed by sensor 430 (and/or processing circuitry 440 of sensor 430). In the example of FIG. 12, sensing module 432 is the same as sensing bridge 100 when sensing bridge 100 is arranged in a gradiometer configuration (shown in FIG. 3A). At step 1212, the electrical current consumption of sensing bridge 100 is determined. At step 1214, a determination is made if the current consumption of sensing bridge 100 is within a predetermined range. In one example, the determination may be made by comparing the current consumption to at least one of a first threshold and a second threshold, where the first threshold represents the lower bound of the range and the second threshold represents the upper bound of the range. In this example, the current consumption may be in the predetermined range when it is greater than the first threshold and less than the second threshold. In another example, the determination may be made by using a current window comparator. If the current consumption is within the predetermined range, process 1200 ends. Otherwise, if the current consumption is outside of the predetermined range, process 1200 proceeds to step 1216. At step 1216, an indication is output indication that sensor 430 is subject to a tampering event. According to the present example, signal 444 is set to ‘1’. However, the present disclosure is not limited to outputting any specific type of indication.

FIG. 12 is provided as an example only. In some implementations, instead of determining current consumption, step 1212 may determine the voltage across sensing bridge 100. In such implementations, step 1214 may determine whether the voltage across the bridge is outside of predetermined bounds. And step 1216 may output an indication of a tampering event if the indication is outside of bounds. The indication may be output in the manner discussed above with respect to step 608 of FIG. 6A.

In some implementations, concurrently with performing any of Methods 1-4, sensor 430 may generate the signal 442 that is indicative of the level of electrical current through the conductor 130. When sensing module 432 is the same as sensing bridge 100 and magnetic feedback loop 436 is provided in sensor 430, the signal 442 may be generated by filtering signal Vbridge to remove components that are attributable to the feedback magnetic field or generating the signal 442 during periods in which the feedback magnetic field is not being applied (e.g., periods in which feedback loop 436 is turned off).

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
a sensing module including a plurality of magnetic field sensing elements, the sensing module being arranged to generate a sensing signal, at least in part, in response to a feedback magnetic field;
a magnetic feedback loop that is configured to generate the feedback magnetic field, the magnetic feedback loop including a feedback coil and a coil driver, the coil driver being arranged to drive the feedback coil with drive current that is generated based on the sensing signal, the drive current having a minimum value and a maximum value; and
electronic circuitry configured to identify a first threshold that corresponds to the maximum value, identify a second threshold that is based on one of (i) maximum resistance associated with a first portion of the sensing module and a maximum resistance associated with a second portion of the sensing module, and (ii) minimum resistance associated with the first portion and a minimum resistance associated with the second portion, detect whether the first threshold is exceeded by the drive current, detect whether the second threshold is exceeded by the sensing signal, and output an indication that the sensor is subject to tampering when the first threshold is exceeded by the drive current and the second threshold is not exceeded by the sensing signal.

2. The sensor of claim 1, wherein the first threshold is a voltage threshold, and detecting whether the first threshold is exceeded by the drive current includes detecting whether a voltage across a sensing resistor in the feedback coil exceeds the voltage threshold.

3. The sensor of claim 1, wherein the electronic circuitry is further configured to output an indication of an overcurrent condition when the first threshold is exceeded by the drive current and the second threshold is exceeded by the sensing signal.

4. The sensor of claim 1, wherein the electronic circuitry is further configured to output an indication that the magnetic feedback loop has failed when the first threshold is not exceeded by the drive current and the second threshold is exceeded by the sensing signal.

5. The sensor of claim 1, wherein:
the sensing module includes a sensing bridge,
the sensing bridge includes a first, second, third, and fourth magnetoresistance (MR) elements,
the first and second MR elements are arranged to form a first leg of the sensing bridge,
the third and fourth MR elements are arranged to form a second leg of the sensing bridge,
the first and second legs are coupled in parallel,
the first portion of the sensing module includes the first and third MR elements,
the second portion of the sensing module includes the second and fourth MR elements,
the maximum resistance associated with the first portion includes a maximum resistance of at least one of the first and third MR elements,
the minimum resistance associated with the first portion includes a minimum resistance of at least one of the first and third MR elements,
the maximum resistance associated with the second portion includes a maximum resistance of at least one of the second and fourth MR elements,
the minimum resistance associated with the second portion includes a minimum resistance of at least one of the second and fourth MR elements.

6. The sensor of claim 1, wherein the sensing signal is further generated in response to a primary magnetic field, the primary magnetic field being generated by a conductor as a result of electrical current flowing through the conductor, and the electronic circuitry is further configured to generate an output signal based on the sensing signal, the output signal being at least in part indicative of a level of an electrical current through the conductor.

7. A sensor, comprising:
a first sensing element that is configured to generate a first sensing signal, the first sensing signal being generated in response to a magnetic field, the first sensing signal having a first maximum value and a first minimum value;
a second sensing element that is configured to generate a second sensing signal, the second sensing signal being generated in response to the magnetic field, the second sensing signal having a second maximum value and a second minimum value; and
an electronic circuitry that is configured to:
identify a first threshold that is based on the first maximum value, a second threshold that is based on the first minimum value, a third threshold that is based on second maximum value, and a fourth threshold that is based on the second minimum value;
compare the first sensing signal against the first threshold;
compare the first sensing signal against the second threshold;
compare the second sensing signal against third threshold;
compare the second sensing signal against the fourth threshold;
detect whether at least one of a first condition and a second condition are satisfied based on an outcome of the comparisons; and
output an indication that the sensor is subject to tampering when either the first condition or the second condition is satisfied;
wherein the first condition is satisfied when the first sensing signal is greater than the first threshold, the first sensing signal is greater than the second threshold, the second sensing signal is greater than the third threshold, and the second sensing signal is greater than the fourth threshold, and
wherein the second condition is satisfied when the first sensing signal is less than the first threshold, the first sensing signal is less than the second threshold, the second sensing signal is less than the third threshold, and the second sensing signal is less than the fourth threshold.

8. The sensor of claim 7, wherein the first sensing element includes a first half-bridge circuit that is formed by using MR elements, and the second sensing elements includes a second half-bridge circuit that is formed by using MR elements.

9. The sensor of claim 7, wherein the first sensing element includes a first full-bridge circuit that is formed by using magnetoresistance (MR) elements, and the second sensing elements includes a second full-bridge circuit that is formed by using MR elements.

10. The sensor of claim 7, wherein the first sensing element includes a first Hall element and the second sensing element includes a second Hall element.

11. The sensor of claim 7, wherein the first and second sensing elements are configured to sense a magnetic field that is associated with an electrical current that is flowing through a conductor, the sensor further comprising processing circuitry that is configured to generate a signal that is indicative of the level of the electrical current, the signal being generated based on the first and second sensing signals.

12. A system, comprising:
a first sensing bridge including a first, second, third, and fourth sensing elements, the first and second sensing elements being arranged to form a first leg of the first sensing bridge, the third and fourth sensing elements being arranged to form a second leg of the first sensing bridge, the first and second legs of the first sensing bridge being coupled in parallel to each other;
an electronic circuitry configured to:
identify a first threshold, a second threshold, a third threshold, and a fourth threshold, the first threshold being smaller than a maximum resistance of at least one of the first and third sensing elements, the second threshold being larger than a minimum resistance of at least one of the first and third sensing elements, the third threshold being smaller than a maximum resistance of at least one of the second and fourth sensing elements, and the fourth threshold being larger than a minimum resistance of at least one of the second and fourth sensing elements;
identify a first resistance of at least one of the first and third sensing elements, the first resistance being an instant resistance;
identify a second resistance of at least one of the second and fourth sensing elements, the second resistance being an instant resistance;
compare the first resistance against the first threshold;
compare the first resistance against the second threshold;
compare the second resistance against third threshold;
compare the second resistance against the fourth threshold; and
detect whether at least one of a first condition and a second condition is satisfied based on an outcome of the comparisons; and
output an indication that the sensor is subject to tampering when either the first condition or the second condition is satisfied;
wherein the first condition is satisfied when the first resistance is greater than the first threshold, the first resistance is greater than the second threshold, the second resistance is greater than the third threshold, and the second resistance is greater than the fourth threshold, and
wherein the second condition is satisfied when the first resistance is less than the first threshold, the first resistance is less than the second threshold, the second resistance is less than the third threshold, and the second resistance is less than the fourth threshold.

13. The sensor of claim 12, wherein:
the first sensing bridge is disposed adjacent to a primary conductor that is arranged to carry electrical current that is being measured by the sensor, and
the first and third sensing elements are disposed on opposite sides of a first section of a feedback coil, the second and fourth sensing elements are disposed on opposite sides of a second section of a feedback coil, the feedback coil being arranged to define a loop, the first section being disposed opposite to the second section.

14. The sensor of claim 12, wherein each of the first, second, third, and fourth sensing elements includes a magnetoresistive (MR) element.

15. The sensor of claim 12, wherein at least a part of the magnetic field is generated as a result of an electrical current flowing through a conductor, and the electronic circuitry is further configured to generate an output of the first sensing bridge.

16. The sensor of claim 12, comprising:
a second sensing bridge that is rotated by approximately 90 degrees relative to the fifth sensing bridge, the second sensing bridge including a fifth, sixth, seventh, and eight sensing elements, the fifth and sixth sensing elements being arranged to form a first leg of the second sensing bridge, the seventh and eight sensing elements being arranged to form a second leg of the second bridge, the first and second legs of the second sensing bridge being coupled in parallel to each other;
wherein the electronic circuitry is further configured to:
identify a fifth threshold, a sixth threshold, a seventh threshold, and a eighth threshold, the fifth threshold being smaller than a maximum resistance of at least one of the fifth and seventh sensing elements, the sixth threshold being larger than a minimum resistance of at least one of the fifth and seventh sensing elements, the seventh threshold being smaller than a maximum resistance of the sixth and eight sensing elements, and the eight threshold being larger than a minimum resistance of at least one of the sixth and eight sensing elements;
identify a third resistance of at least one of the fifth and seventh sensing elements, the third resistance being an instant resistance;
identify a fourth resistance of at least one of the sixth and eighth sensing elements, the fourth resistance being an instant resistance;
compare the third resistance against the fifth threshold;
compare the third resistance against the sixth threshold;
compare the fourth resistance against seventh threshold;
compare the fourth resistance against the eight threshold;
detect whether at least one of a third condition and a fourth condition are satisfied based on an outcome of the comparisons; and
output an indication that the sensor is subject to tampering when either the third condition or the fourth condition is satisfied;
wherein the third condition is satisfied when: the third resistance is greater than the fifth threshold, the third resistance is greater than the sixth threshold, the fourth resistance is greater than the seventh threshold, and the fourth resistance is greater than the eight threshold, and
wherein the fourth condition is satisfied when the third resistance is less than the fifth threshold, the third resistance is less than the sixth threshold, the fourth resistance is less than the seventh threshold, and the fourth resistance is less than the eight threshold.

17. The sensor of claim 16, wherein each of the fifth, sixth, seventh, and eighth sensing elements includes an MR element.

18. A sensor, comprising:
a first sensing bridge that is configured to generate a first sensing signal, the first sensing signal being generated in response to a magnetic field, the first sensing bridge having a first minimum resistance and a first maximum resistance;
a second sensing bridge that is configured to generate a second sensing signal, the second sensing signal being generated in response to the magnetic field, the second sensing bridge having a second minimum resistance and a second maximum resistance, the second sensing bridge being rotated at approximately 90 degrees relative to the first sensing bridge; and
an electronic circuitry that is configured to:
identify a first threshold that is based on the first maximum resistance, a second threshold that is based on the first minimum resistance, a third threshold that is based on the second maximum resistance, and a fourth threshold that is based on the second minimum resistance;
identify a first resistance of the first sensing bridge, the first resistance being an instant resistance of the first sensing bridge;
identify a second resistance of the second sensing bridge, the second resistance being an instant resistance of the second sensing bridge;
compare the first resistance against the first threshold;
compare the first resistance against the second threshold;
compare the second resistance against third threshold;
compare the second resistance against the fourth threshold;
detect whether at least one of a first condition, a second condition, a third condition, and a fourth condition are satisfied based on an outcome of the comparisons; and
output an indication that the sensor is subject to tampering when any one of the first condition, second condition, third condition, and fourth condition is satisfied;
wherein the first condition is satisfied when: the first resistance is greater than the first threshold, the first resistance is greater than the second threshold, the second resistance is less than the third threshold, and the second resistance is greater than the fourth threshold;
wherein the second condition is satisfied when: the first resistance is less than the first threshold, the first resistance is less than the second threshold, the second resistance is less than the third threshold, and the second resistance is greater than the fourth threshold;
wherein the third condition is satisfied when: the first resistance is less than the first threshold, the first resistance is greater than the second threshold, the second resistance is greater the third threshold, and the second resistance is greater than the fourth threshold;
wherein the fourth condition is satisfied when: the first resistance is less than the first threshold, the first resistance is greater than the second threshold, the second resistance is less than the third threshold, and the second resistance is less than the fourth threshold.

19. The sensor of claim 18, wherein the first sensing bridge includes a first plurality of magnetoresistors and the second sensing bridge includes a second plurality of magnetoresistors.

20. A sensor, comprising:
a sensing module including a plurality of magnetic field sensing elements, the sensing module being arranged to generate a sensing signal, at least in part, in response to a reference magnetic field and a primary magnetic field that is generated as a result of an electrical current flowing through a conductor, the reference magnetic field having a first frequency and the primary magnetic field having a second frequency that is different from the first frequency;
a coil that is configured to generate the reference magnetic field; and
electronic circuitry configured to: filter the sensing signal so as to block components of the sensing signal that correspond to the second frequency; calculate, based on the filtered sensing signal, a value of a metric that is at least in part indicative of a sensitivity of the sensing module;
compare the value of the metric against a threshold; and output an indication that the sensor is subject to tampering when the value of the metric is less than the threshold.

21. The sensor of claim 20, wherein the first frequency is greater than the second frequency, and the sensing signal is filtered by using a high-pass filter that is arranged to block the first frequency.

22. The sensor of claim 20, wherein the first frequency is less than the second frequency, and the sensing signal is filtered by using a low-pass filter that is arranged to block the first frequency.

23. The sensor of claim 20, wherein the value of the metric is calculated based on a level of a drive current that is used to drive the coil, and a level of the sensing signal.

24. The sensor of claim 20, wherein the electronic circuitry is further configured to generate an output signal that is at least indicative of a level of the electrical current.

25. The sensor of claim 20, wherein the sensing module includes a sensing bridge including a plurality of magnetoresistors.

26. The sensor of claim 20, wherein each of the magnetic field sensing elements includes a Hall element.

27. A sensor, comprising:
a gradiometer including a plurality of magnetoresistors, the gradiometer being configured to generate a sensing signal in response to a magnetic field that is at least in part produced as a result of an electrical current flowing through a conductor; and
electronic circuitry configured to detect an electrical current consumption of the gradiometer, compare the electrical current consumption against at least one of a first threshold and a second threshold, and output an indication that the sensor is subject to tampering based on an outcome of the comparison.

28. The sensor of claim 27, wherein the indication is output when the electrical current consumption below the first threshold or above the second threshold.

29. The sensor of claim 27, wherein the comparison is performed by using a window comparator.

30. The sensor of claim 27, wherein the conductor is curved, the gradiometer is implemented as a sensing bridge including a first leg that is coupled in parallel with a second leg, the first leg including at least two magnetoresistors that are disposed adjacent to different end portions of the conductor, and the second leg including at least two other magnetoresistors that are disposed adjacent to different ones of the end portions of the conductor.

31. The sensor of claim 27, wherein the electronic circuitry is configured to generate an output signal based on the sensing signal, the output signal being indicative of a level of the electrical current that is flowing through the conductor.
